(19) United States
(12) Patent Application Publication
(10) Pub. No.: US 2011/0281431 A1
(43) Pub. Date: Nov. 17, 2011

(54) METHOD OF PATTERNING THIN METAL FILMS

(75) Inventor: Christian A. WITT, Woodbridge, CT (US)

(73) Assignee: GLOBALFOUNDRIES Inc., Grand Cayman (KY)

(21) Appl. No.: 12/780,242

(22) Filed: May 14, 2010

(51) Int. Cl. H01L 21/4763

(52) U.S. Cl. 438/618; 257/E21.496

(57) ABSTRACT

A Cu interconnect is formed with improved directionality and smoothness. Embodiments include wet etching Cu while applying a pulsing electric current. An embodiment includes forming a Cu layer, and patterning the Cu layer by exposing it to a wet etching solution which includes a passivating surface active agent while simultaneously applying an electric current. The etching solution may be a mild acid. A UV light may be applied simultaneously with the electric current. The electric current may be pulsed with a cycle frequency between 50 kHz and 500 kHz.

### TECHNICAL FIELD

The present disclosure relates to methods for forming semiconductor metal interconnects. The present disclosure is particularly applicable to 32 nanometer (nm) technology nodes and beyond.

### BACKGROUND

Conventional methods of fabricating back-end-of-line (BEOL) metal interconnect layers employ a copper or copper alloy (Cu) inlay or damascene process, because of difficulties in patterning blanket Cu metal films into interconnect traces. As reductions in device scaling continue, front-end-of-line (FEOL) transistor size becomes smaller, and the number of transistors per unit area increases. Correspondingly, BEOL metal interconnect line pitch decreases. As the metal trench width is reduced, the trench aspect ratio increases, making it increasingly more difficult to deposit barrier/seed layers with good uniformity and integrity, and without creating voids.

Reactive ion etching (RIE) or short RIE is typically used for aluminum (Al), as it has the advantage of producing an anisotropic or directional etch pattern. This allows for approximately rectangular interconnect cross sections, which in turn allows for high interconnect densities, as required for modern microchips. However, RIE is difficult to apply to Cu, since Cu does not readily form volatile compounds for a dry etching process, except with high temperatures that are destructive to the semiconductor features. Furthermore, chloride used for the dry etch process poisons Cu. In addition, traditional wet etching processes for Cu, as used, for example, on printed circuit boards, produce rough and grainy interconnects on a microscale, rendering them unsuitable for deep submicron interconnects.

A need therefore exists for improved methodology enabling the formation of Cu interconnects, particularly for 32 nm node technologies and beyond.

### SUMMARY

An aspect of the present disclosure is an improved method of fabricating a metal interconnect by wet etching while applying a pulsed current.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method of fabricating a metal interconnect, the method comprising: forming a Cu or Cu alloy layer; and patterning the Cu layer by exposing the Cu layer to a wet etching solution, comprising a passivating surface active agent, while applying an electric current.

Aspects of the present disclosure include the passivating surface active agent comprising a nonionic surfactant. Further aspects include applying an ultraviolet (UV) light to the Cu layer during patterning. Another aspect includes applying a pulsed electric current with a square waveform. Additional aspects include applying a pulsed electric current with pulse heights between 100 millivolts (mV) and 1 volt (V) and pulse on times between 1 microsecond (μs) and 10 μs. Other aspects include applying the pulsed electric current with a cycle frequency between 50 kHz and 500 kHz, such as between 150 kHz and 400 kHz. Further aspects include the etching solution comprising a mild acid. Additional aspects include forming a masking layer on the Cu layer; and patterning the masking layer prior to patterning the Cu layer. Another aspect includes forming a masking layer that is resistant to the etching solution. Other aspects include forming a photoresist as the masking layer. Further aspects include forming the Cu layer on a continuous metal adhesion layer, and removing the metal adhesion layer after patterning the Cu layer. Additional aspects include forming the adhesion layer of tantalum (Ta).

Another aspect of the present disclosure is a method of fabricating a metal interconnect, the method comprising: forming a continuous metal adhesion layer on a substrate; forming a Cu or Cu alloy layer on the metal adhesion layer; forming a masking layer on the Cu layer; lithographically patterning the masking layer, thereby exposing a portion of the Cu layer; applying a wet etching solution, comprising a passivating surface active agent, to the exposed portion of the Cu layer; and simultaneously with the application of the etching solution, applying a pulsing electric current, using the metal adhesion layer and the Cu layer as the electrodes.

Aspects include applying an ultraviolet (UV) light to the Cu layer during application of the etching solution. Further aspects include applying a pulsing electric current with a square waveform. Another aspect includes applying the pulsing electric current with a cycle frequency between 50 kHz and 500 kHz. Additional aspects include applying an acid with a static etch rate less than 10 nm per minute as an etching solution. Other aspects include forming the masking layer of a material that is resistant to the acid and adheres to the Cu.

Another aspect of the present disclosure is a method of fabricating a metal interconnect, the method comprising: forming a Cu or Cu alloy layer; forming a wet etching solution comprising a passivating surface active agent; and patterning the Cu layer by exposing the Cu layer to the etching solution while applying a pulsed electric current.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the description is to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates sequential layers in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the rough, grainy topography and patterning difficulties attendant upon forming submicron interconnects by conventional processes. In accordance with embodiments of the present disclosure, an electroetch approach is employed. Consequently, the process eliminates Cu fill issues, does not require the high temperatures necessary for dry etching, and produces smooth directional interconnects.

Methodology in accordance with embodiments of the present disclosure includes forming a Cu or Cu alloy layer, and patterning the Cu layer by exposing the Cu layer to a wet etching solution, comprising a passivating surface active agent, while applying an electric current.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the description is to be regarded as illustrative in nature, and not as restrictive.

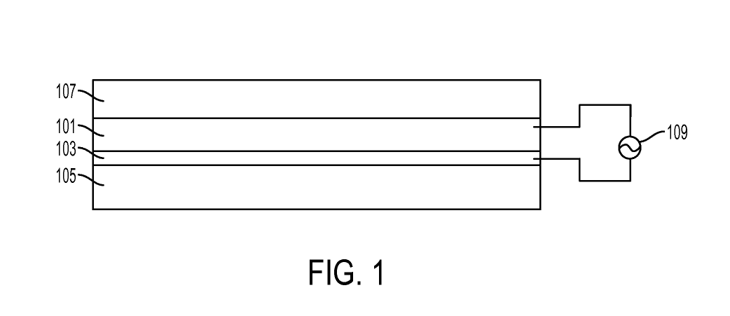

Adverting to FIG. 1, in accordance with an exemplary embodiment, a Cu film 101 is formed on a continuous conductive barrier/adhesion layer 103, which is formed on a substrate 105. Specifically, Cu is deposited by a sequence of adhesion layers (liners), which are typically tantalum (Ta) based, a thin Cu seed, and thicker electroplated Cu. Cu film 101 may be deposited to a thickness less than 1 micron (μm). A masking layer 107 is formed over the Cu sheet. The masking layer 107 may be formed of a photoresist, or a hardmask layer. The masking layer 107 may be formed of a material that is resistant to etching by the Cu etching solution, adheres to Cu, and is wettable by aqueous solutions. Accordingly, the masking layer 107 may be a nonconductive layer, such as a polymer layer. Alternatively, the masking layer 107 may be a conductive layer, for example Ta, titanium (Ti), titanium nitride (TiN), platinum (Pt), and palladium (Pd). The masking layer 107 may be patterned by a conventional lithographic technique, e.g., using a second photoresist as a mask.

The Cu film 101 with the patterned mask 107 thereon is then exposed to an etching solution while being subjected to an electric current 109. The barrier/adhesion layer functions as a conduit for the electrical etching current, which is applied using the Cu as the second electrode. The etching solution may be applied by immersion, spray, jet, or other conventional techniques that allow electric current flow. The etching solution is typically a mild acid solution, e.g., having a static etch rate less than 10 nm/minute (min), for example less than 5 nm/min, e.g, less than 2 nm/min, and is generally similar to electropolish solutions, such as a dilute phosphoric acid solution. The Cu wafer 101 is generally polarized anodically, as by dissolving Cu into the etchant solution.

The electric current 109 may be applied in pulsed form using a square waveform and a cycle frequency of, for example, 50 kilohertz (kHz) to 500 kHz, e.g., 150 kHz to 300 or 400 kHz, with pulse on times of 1 to 10 microseconds (μs). Pulse heights may be 100 millivolts (mV) to 1 volt (V), for example 150 mV to 600 mV. The effective current density (that is the average, or equivalent DC current density) may be 1 milliamps (mA)/cm² to 100 mA/cm², e.g., 10 mA/cm² to 100 mA/cm². The electrochemical etching may be ultraviolet (UV) assisted. For example, the etching may be performed under illumination of a UV lamp (not shown for illustrative convenience) with 5 watts (W) to 500 W power. In addition, a passivating surface active agent (suppressor) is added that protects Cu from dissolving during the cycle-off time.

The suppressor may be a nonionic surfactant or an ionic surfactant. For example, the suppressor may be a non-polymeric agent including, without limitation, non-polymeric sulfur-containing and non-polymeric nitrogen-containing compounds. Exemplary sulfur-containing leveling compounds include thiourea and substituted thioureas. Exemplary nitrogen-containing compounds include primary, secondary, and tertiary amines. Such amines may be alkyl amines, aryl amines, and cyclic amines (cyclic compounds having a nitrogen as a member of the ring). Suitable amines include, but are not limited to, dialkylamines, trialkylamines, arylalkylamines, diarylamines, imidazole, triazole, tetrazole, benzimidazole, benzotriazole, piperidine, morpholine, piperazine, pyridine, oxazole, benzoxazole, pyrimidine, quonoline, isoquinoline, and the like. Imidazole and pyridine are particularly suitable. Other suitable non-polymeric leveling agents include nigrosines, pentamethyl-para-rosaniline hydrohalide, hexamethyl-para-rosaniline hydrohalide, and compounds containing a functional group of the formula N—R—S, where R is a substituted alkyl, unsubstituted alkyl, substituted aryl or unsubstituted aryl.

The suppressor may alternatively be, for example, a polymeric material, such as one having heteroatom substitution, e.g., oxygen substitution. Exemplary suppressors are high molecular weight polyethers, such as those of the formula: R—O—(CXYCX′Y′O)_{nR}, where R and R′ are independently chosen from H, (C₂-C₂₀)alkyl group and (C₆-C₁₀)aryl group; each of X, Y, X′ and Y′ is independently selected from hydrogen, alkyl such as methyl, ethyl, or propyl, aryl such as phenyl, or aralkyl such as benzyl; and n is an integer from 5 to 100,000. Typically, one or more of X, Y, X′ and Y′ is hydrogen. Particularly suitable suppressors include commercially available polypropylene glycol copolymers and polyethylene glycol copolymers, including ethylene oxide-propylene oxide (“EO/PO”) copolymers and butyl alcohol-ethylene oxide-propylene oxide copolymers. Suitable butyl alcohol-ethylene oxide-propylene oxide copolymers are those having a weight average molecular weight of 1800. When such suppressors are used, they are typically present in an amount in the range of from 1 to 10,000 ppm based on the weight of the bath, and preferably from 5 to 10,000 ppm.

The suppressor may also be an alkylene glycol, for example, ethylene glycol, 1,2 propylene glycol, 1,3-propylene glycol, glycerol, 1,3-butylene glycol, 1,4-butylene glycol, 2,3-butylene glycol, 1,5-pentanediol, 1,6-hexanediol, 1,8-octanediol, 1,9-nonanediol, 1,10-decanediol, neopentyl glycol, 1,4-cyclohexanedimethanol, 2-methyl-1,3-propanediol, 2,2,4-trimethyl-1,3-pentanediol, diethylene glycol, dipropylene glycol, triethylene glycol, tripropylene glycol, dibutylene glycol, polyethylene glycol, polypropylene glycol, polytetramethylene glycol, and the like, and combinations thereof. A preferred alkylene glycol comprises ethylene glycol or propylene glycol. The high frequency pulsing current 109 in combination with the suppressor achieves the directionality and smoothness required for quality interconnects with widths up to 75 nm.

The embodiments of the present disclosure achieve several technical effects, including quality interconnects with directionality and smoothness, as well as good uniformity and integrity. Further, compared to dry reactive ion etching, the wet etching approach is more cost effective, as no expensive vacuum and gas handling equipment is required, and the operation may be carried out at room temperature, as opposed to most halide based RIE processes. Together, the process is significantly simpler, and hence is easier to incorporate in actual process development. The present disclosure enjoys industrial applicability in any of various types of highly integrated semiconductor devices particularly 32 nanometer (nm) node devices and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method of fabricating a metal interconnect, the method comprising:
forming a copper or copper alloy (Cu) layer; and
patterning the Cu layer by exposing the Cu layer to a wet etching solution, comprising a passivating surface active agent, while applying an electric current.

2. The method according to claim 1, wherein the passivating surface active agent comprises a nonionic surfactant.

3. The method according to claim 1, further comprising applying an ultraviolet (UV) light to the Cu layer during patterning.

4. The method according to claim 1, comprising, applying a pulsed electric current with a square waveform.

5. The method according to claim 4 comprising applying a pulsed electric current with pulse heights between 100 millivolts (mV) and 1 volt (V) and pulse on times between 1 microsecond (μs) and 10 μs.

6. The method according to claim 4, comprising applying the pulsed electric current with a cycle frequency between 50 kHz and 500 kHz.

7. The method according to claim 6, comprising applying the pulsed electric current with a cycle frequency between 150 kHz and 400 kHz.

8. The method according to claim 1, wherein the etching solution comprises a mild acid.

9. The method according to claim 1, further comprising:
forming a masking layer on the Cu layer; and
patterning the masking layer prior to patterning the Cu layer.

10. The method according to claim 9, comprising forming a masking layer that is resistant to the etching solution.

11. The method according to claim 9, comprising forming a photoresist as the masking layer.

12. The method according to claim 1, comprising: forming the Cu layer on a continuous metal adhesion layer, and removing the metal adhesion layer after patterning the Cu layer.

13. The method according to claim 12, comprising forming the adhesion layer of tantalum (Ta).

14. A method of fabricating a metal interconnect, the method comprising:
forming a continuous metal adhesion layer on a substrate;
forming a copper or copper alloy (Cu) layer on the metal adhesion layer;
forming a masking layer on the Cu layer;
lithographically patterning the masking layer, thereby exposing a portion of the Cu layer;
applying a wet etching solution, comprising a passivating surface active agent, to the exposed portion of the Cu layer; and
simultaneously with the application of the etching solution, applying a pulsing electric current, using the metal adhesion layer and the Cu layer as the electrodes.

15. The method according to claim 14, further comprising applying an ultraviolet (UV) light to the Cu layer during application of the etching solution.

16. The method according to claim 14, comprising applying a pulsing electric current with a square waveform.

17. The method according to claim 14, comprising applying the pulsing electric current with a cycle frequency between 50 kHz and 500 kHz.

18. The method according to claim 14, comprising applying an acid with a static etch rate less than 10 nm per minute as an etching solution.

19. The method according to claim 18, comprising forming the masking layer of a material that is resistant to the acid and adheres to the Cu.

20. A method of fabricating a metal interconnect, the method comprising:
forming a copper or copper alloy (Cu) layer;
forming a wet etching solution comprising a passivating surface active agent; and
patterning the Cu layer by exposing the Cu layer to the etching solution while applying a pulsed electric current.
